(19) United States
(12) Patent Application Publication
(10) Pub. No.: US 2007/0221993 A1
(43) Pub. Date: Sep. 27, 2007

(54) Method for making a thermally stable silicide

(75) Inventors: Shau-Lin Shue, Hsinchu (TW); Chen-Hua Yu, Hsinchu (TW); Cheng-Tung Lin, Hsinchu County (TW); Chii-Ming Wu, Taipei (TW); Shih-Wei Chou, Taipei (TW); Gin Jei Wang, Taipei City (TW); Cp Lo, Hsinchu (TW); Chih-W Chang, Hsinchu (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Taiwan Semiconductor Manufacturing Company, Ltd.

(21) Appl. No.: 11/389,309

(22) Filed: Mar. 27, 2006

(51) Int. Cl. H01L 27/12; H01L 27/01; H01L 31/0392

(52) U.S. Cl. 257/350

(57) ABSTRACT

A semiconductor device and method of manufacturing are provided that include forming an alloy layer having the formula MbX over a silicon-containing substrate, where Mb is a metal and X is an alloying additive, the alloy layer being annealed to form a metal alloy silicide layer on the gate region and in active regions of the semiconductor device.

### TECHNICAL FIELD

The present invention generally relates to a semiconductor device and a method of making a semiconductor device. More particularly, this invention relates to the formation of silicides on semiconductor devices. The present invention provides a simple method to improve alloy silicide thermal stability, having a large post silicidation temperature range.

### DESCRIPTION OF THE RELATED ART

Silicides, which are compounds formed from a metal and silicon, are commonly used for contacts in semiconductor devices. Silicide contacts provide a number of advantages over contacts formed from other materials, such as aluminum or polysilicon. Silicide contacts are thermally stable, have lower resistivity than polysilicon, and are good ohmic contacts. Silicide contacts are also reliable, since the silicidation reaction eliminates many defects at an interface between a contact and a device feature.

A common technique used in the semiconductor manufacturing industry is self-aligned silicide (“salicide”) processing. Salicide processing is used in the fabrication of high-speed complementary metal oxide semiconductor (CMOS) devices. The salicide process converts the surface portions of the source, drain, and gate silicon regions into a silicide. Salicide processing involves the deposition of a metal that undergoes a silicidation reaction with silicon (Si), but not with silicon dioxide or silicon nitride. In order to form salicide contacts on source, drain, and gate regions of a semiconductor wafer, oxide spacers are provided next to the gate regions. The metal is then blanket deposited on the wafer. After heating the wafer to a temperature at which the metal reacts with the silicon of the source, drain, and gate regions to form contacts, unreacted metal is removed. Silicide contact regions remain over the source, drain, and gate regions, while unreacted metal is removed from other areas.

FIGS. 1(a)-1(d) illustrate a conventional salicide process. In FIG. 1(a), a substrate 100 is a conventional semiconductor substrate, such as a single-crystal silicon substrate, which may be doped p-type or n-type. Active regions 120 are, for example, transistor source regions or drain regions. Active regions 120 are conventionally isolated from active regions of other devices by field oxide regions 110. Field oxide regions 110 may be formed by local oxidation of silicon (LOCOS) methods, or by shallow trench isolation (STI) methods, for example. Active regions 120 may be n-type or p-type doped silicon, and may be formed according to known methods.

A conventional gate region 130 is formed on a gate oxide 125. Gate region 130 may comprise doped polysilicon. Spacers 140, which may be oxide spacers, are formed on the sidewalls of gate region 130.

In FIG. 1(b), a metal alloy layer 150 is deposited over the surface of substrate 100. Metal alloy layer 150 comprises NiX, where X is an alloying additive. While Ni is used in this example of metal alloy layer 150, other metals may be used.

After deposition of metal alloy layer 150, two rapid thermal anneal (RTA) steps are performed to achieve silicidation. During the silicidation process, silicon from active regions 120 and gate region 130 diffuses into metal alloy layer 150, and/or metal from metal alloy layer 150 diffuses into silicon-containing active regions 120 and gate region 130. One or more metal silicide regions form from this reaction. When the metal alloy layer 150 includes a metal that, upon heating, forms a silicide with elemental silicon (crystalline, amorphous, or polycrystalline), but not with other silicon-containing molecules (like silicon oxide or silicon nitride), the silicide is termed a salicide.

FIG. 1(c) illustrates the result of the two RTA steps. The first RTA step forms a Ni-rich alloy silicide layer, such as Ni₂XSi (not shown). The second RTA step forms a lower Ni content Ni alloy silicide (NiXSi). FIG. 1(c) thus shows a Ni alloy silicide 160 over gate region 130 and in active regions 120. Unreacted or not fully reacted metal alloy layer 150 remains over spacers 140.

As shown in FIG. 1(d), after silicidation, the unreacted metal alloy layer 150 is removed, for example, by a selective etch process. If the metal alloy layer 150 includes Ni, unreacted Ni/Ni alloy may be removed by wet chemical stripping. After removal of the unreacted metal, the remaining silicide regions provide electrical contacts for coupling the active regions and the gate region to other features on the semiconductor device.

In the conventional process shown in FIGS. 1(a)-1(d), commonly used salicide materials include TiₓSi_{y}, NiₓSi_{y}, PtSi, Pd₂Si, and NiSi, among others. Although NiSi provides some advantages over TiSi₂ and CoSi₂, for example, such as lower silicon consumption during silicidation, it is not widely used because of the difficulty in forming NiSi rather than the higher resistivity nickel di-silicide, NiSi₂. Even though back end processing temperatures below 500° C. can now be achieved, forming NiSi without significant amounts of NiSi₂ remains a challenge, since formation of NiSi₂ has been seen at temperatures as low as about 450° C. Furthermore, the thermal stability of silicides formed from pure Ni, Ti, Co, Pt, or Pd was not sufficient because of easy agglomeration occurring during high temperature processing. In addition, the conventional method described above has problems caused by native oxide left behind after processing.

The present invention is directed to overcome one or more of the problems of the related art.

### SUMMARY OF THE INVENTION

In accordance with the purpose of the invention as embodied and broadly described, there is provided a semiconductor device, comprising: a substrate; a gate dielectric overlying the substrate; a gate electrode overlying the gate dielectric; source/drain regions adjacent to opposite sides of the gate electrode; a layer of refractory metal or refractory metal compound overlying the gate electrode and source/drain regions; and a metal alloy silicide overlying the layer of refractory metal or refractory metal compound.

In accordance with the present invention, there is also provided a semiconductor transistor comprising: a gate dielectric overlying a substrate; a gate electrode overlying the gate dielectric; a spacer formed on sidewalls of the gate electrode; a layer of refractory metal or refractory metal compound overlying active regions of the substrate; and an MX metal alloy layer formed on the layer of refractory metal or refractory metal compound, wherein the M is selected from the group consisting of Ti, Pt, Pd, Co, and Ni, and further wherein the X includes an alloying additive.

Additional features and advantages of the invention will be set forth in the description that follows, being apparent from the description or learned by practice of the invention. The objectives and other advantages of the invention will be realized and attained by the semiconductor device structures and methods of manufacture particularly pointed out in the written description and claims, as well as the appended drawings.

It is to be understood that both the foregoing general description and the following detailed description are exemplary and explanatory, and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings:

FIGS. 1(a)-1(d) illustrate cross-sectional views of part of a conventional salicide processing sequence; and

FIGS. 2(a)-2(e) illustrate cross-sectional views of part of a salicide processing sequence consistent with embodiments of the present invention.

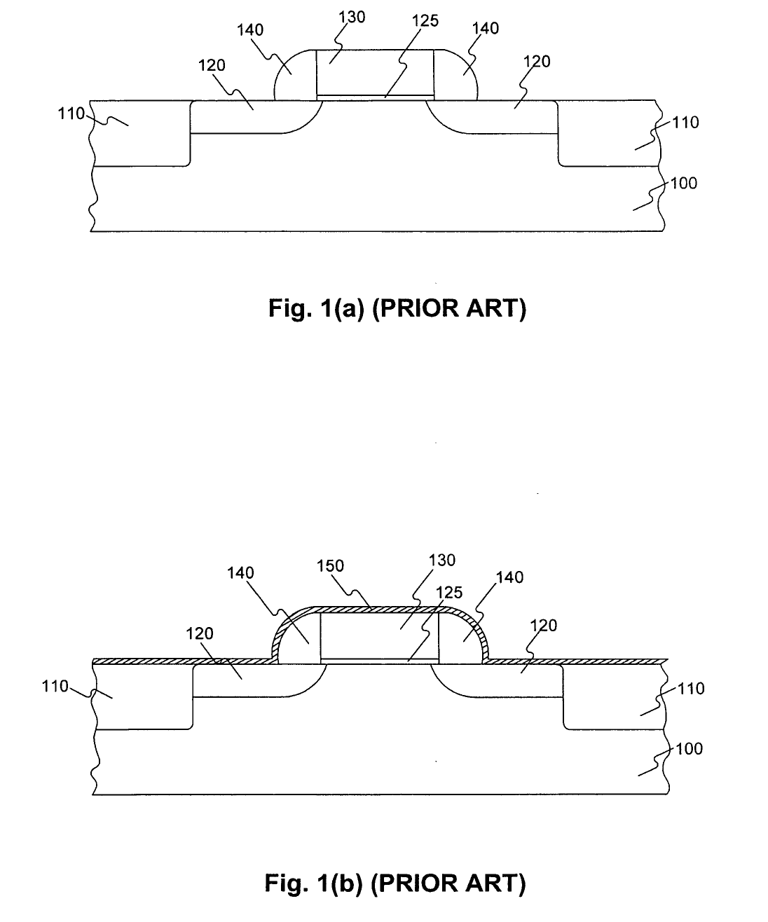

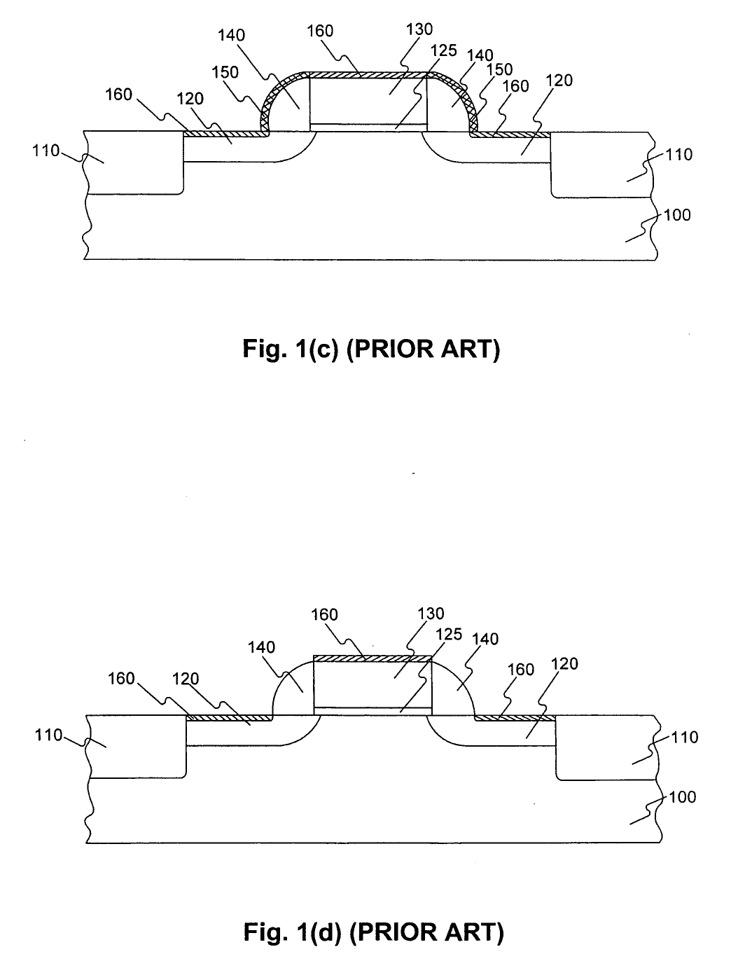

### DESCRIPTION OF THE EMBODIMENTS

Reference will now be made in detail to embodiments of the present invention, examples of which are illustrated in the accompanying drawings. Wherever possible, the same or similar reference numbers will be used throughout the drawings to refer to the same or like parts.

Embodiments consistent with the present invention provide for a simplified salicide process with better stability for NiPtSi, NiSi, PtSi, Pd₂Si, TiSi₂, CoSi₂ silicides, which allows for a larger post silicidation processing temperature range. The present invention is applicable to salicide processing in semiconductor devices having shallow junctions and/or thin silicon-on-insulator (SOI) films.

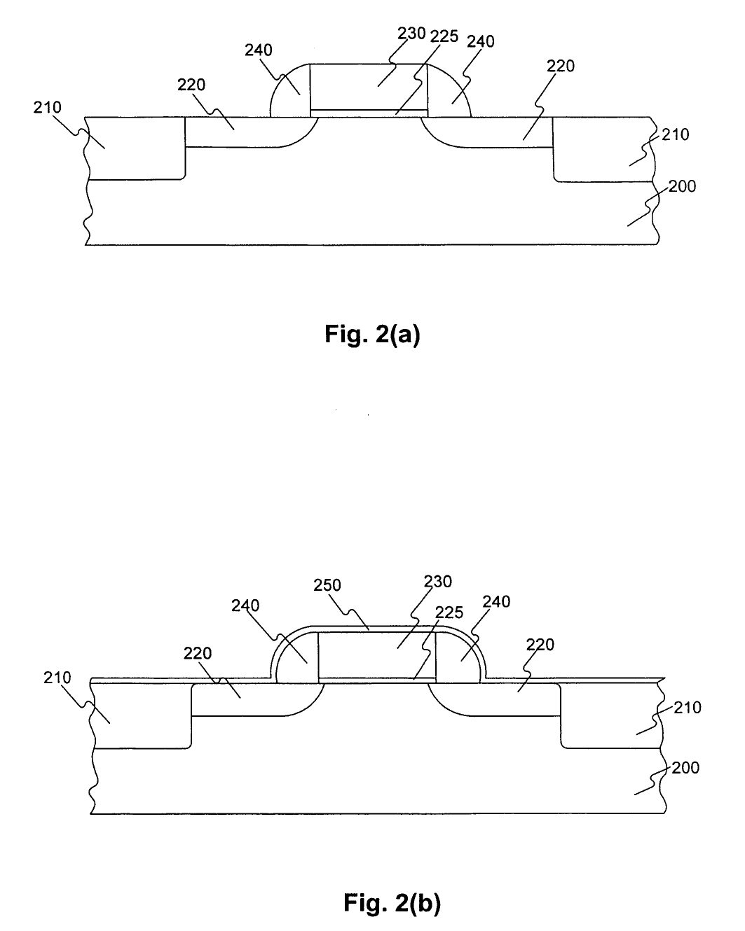

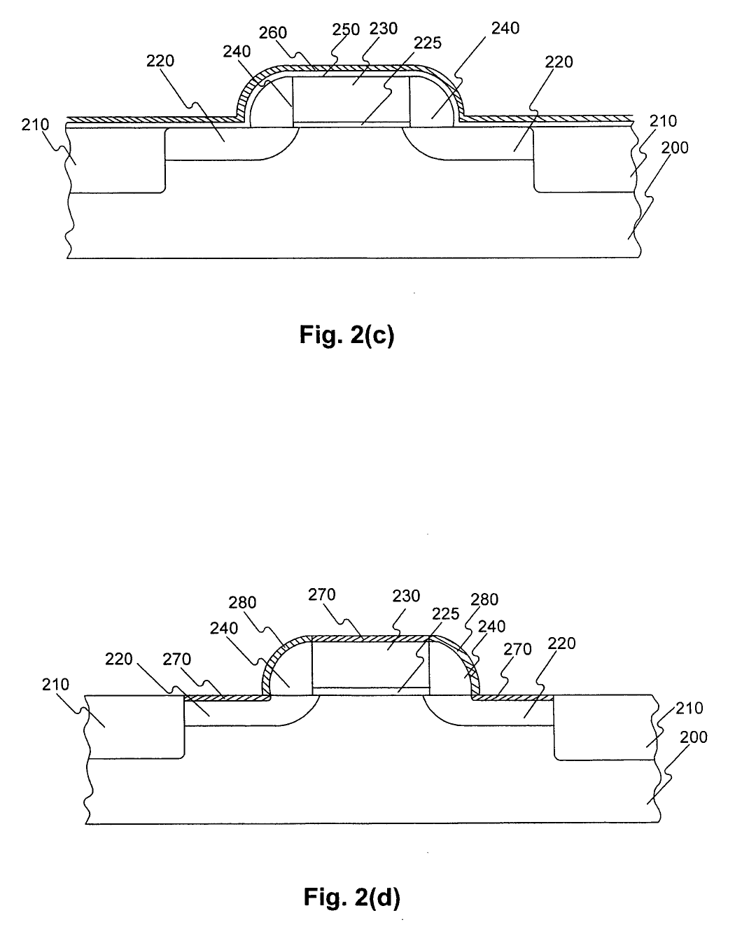

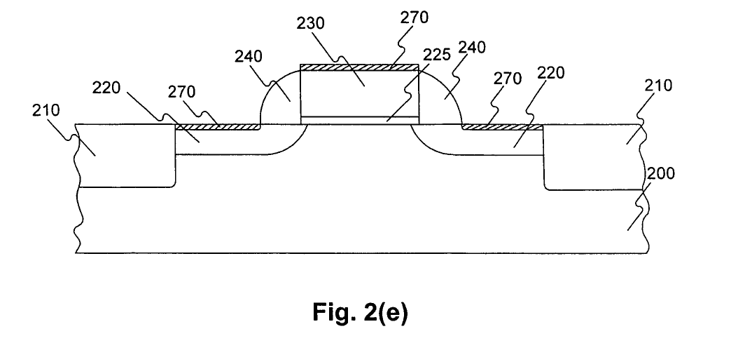

To solve problems associated with the approaches in the related art discussed above and consistent with an aspect of the present invention, package structures consistent with the present invention will next be described with reference to FIGS. 2(a)-2(e).

FIGS. 2(a)-2(e) illustrate a salicide process according to an embodiment of the present invention. In FIG. 2(a), a substrate 200 is a semiconductor substrate, such as a single-crystal silicon substrate, which may be doped p-type or n-type. Active regions are, for example, transistor source region and drain regions 20 and a gate region 230. Active regions including source and drain regions 220 and gate region 230, are isolated from active regions of other devices by isolation regions 210. Isolation regions 210 may be formed by local oxidation of silicon (LOCOS) methods, or by shallow trench isolation (STI) methods, for example. Source and drain regions 220 may be n-type or p-type doped silicon, and may be formed according to known methods.

Gate region 230 is formed on a gate dielectric 225. Gate region 230, e.g. a gate electrode, may comprise doped polysilicon. Gate dielectric 225 and gate region 230 may be formed according to known processing steps. After processing and silicide formation (described later), gate region 230 may be about 20 Å thick to about 100 Å thick, and may also be comprised of Ni, Pt, Ti, Co, Si, or a Ni alloy silicide, or any combination thereof. Preferably, gate region 230 may comprise NiPtSi. Spacers 240, which may be oxide spacers, or a combination of oxide and nitride spacers, are formed on the sidewalls of gate region 230. Consistent with an embodiment of the present invention, substrate 200 may comprise Si and at least one of SiO₂, SiON, SiN, SiCO, SiCN, SiCON, and SiGe. Further, spacers 240 may be doped with at least one of H, B, P, As, and In during the implantation step of doping substrate 200. After the profile of spacers 240 is defined, the substrate 200 may be placed in an HF dip to remove any remaining undesired oxide. Consistent with the present invention, the resultant transistor structure may be a FinFET.

In FIG. 2(b), a layer 250 of refractory metal or refractory metal compound is formed over the surface of active regions 220 and gate region 230. Metal layer 250 may be Ti, Ta, W, or Mo, or a compound thereof that may be formed, for example, by sputter deposition using a Mo target doped with Ti. Preferably, metal layer 250 may be Ti and be about 10 Å to about 100 Å thick. More preferably, metal layer 250 may be about 10 Å to about 20 Å thick. Metal layer 250 may be formed, for example, by atomic layer deposition (ALD), or any other suitable deposition process. After deposition of metal layer 250, an alloy layer 260 is deposited as shown in FIG. 2(c). Alloy layer 260 may be deposited by any suitable process. Alloy layer 260 may be defined as an MX alloy, where M is selected from the group consisting of Ti, Pt, Pd, Co, and Ni, and X includes an alloying additive. The alloying additive may be selected from the group consisting of: C, Al, Si, Sc, Ti, V, Cr, M, Fe, Co, Ni, Cu, Ge, Y, Zr, Nb, Mo, Ru, Rh, Pd, In, Sn, La, Hf, Ta, W, Re, Ir, Pt, Ce, Pr, Nd, Sm, Eu, Gd, Tb, Dy, Ho, Er, Tm, Yb, Lu, and mixtures thereof. Further, an optional TiN cap layer (not shown) may be deposited on alloy layer 260.

The device shown in FIG. 2(c) is then subjected to an annealing step, for example, a rapid thermal anneal (RTA) step, to achieve silicidation by reaction of alloy layer 260 with underlying Si. Preferably, only one annealing step is performed, though, two annealing steps could be performed without departing from the scope of the invention. The annealing step that forms the salicide may be performed for about 10 seconds to about 180 seconds, at a temperature of about 300° C. to about 500° C., and in an atmosphere of N₂, He, or in a vacuum. Consistent with the present invention, the annealing step may be performed in a furnace, by rapid thermal anneal (RTA), in a physical vapor deposition (PVD) chamber, or on a hot plate. Preferably, the anneal step is a RTA. When the alloy layer 260 includes metal that, upon heating, forms a silicide with elemental silicon (crystalline, amorphous, or polycrystalline), but not with other silicon-containing molecules (like silicon oxide or silicon nitride), the silicide is termed a salicide.

A result of the salicide process is shown in FIG. 2(d), which illustrates a Ni alloy silicide 270 on gate region 230 and in active regions 220, and an unreacted or not fully reacted metal layer 280 on spacers 240. Preferably, Ni alloy silicide 270 may be NiPtSi. Alternatively, the present invention contemplates a variety of possible silicide phases, including, but not limited to, Ni₂₍ₓ₎Pt₍ₛ₁₋₂₍ₓ₎₎Si.

As shown in FIG. 2(e), after the salicide process, the unreacted metal alloy layer 280 is removed, for example, by a selective etch process. Unreacted metal alloy layer 280 may be removed by wet chemical stripping or a dry etching method. After removal of the unreacted metal, the remaining Ni alloy silicide 270, shown on gate region 230 and in active regions 220, provides electrical contacts for coupling the active regions and the gate region to other features on the semiconductor device. Consistent with the present invention, a contact etch stop (CESL) may be formed on top of Ni alloy silicide 270.

It will be apparent to those skilled in the art that various modifications and variations can be made in the disclosed structures and methods without departing from the scope or spirit of the invention. Other embodiments of the invention will be apparent to those skilled in the art from consideration of the specification and practice of the invention disclosed herein. It is intended that the specification and examples be considered exemplary only, with a true scope and spirit of the invention being indicated by the following claims.

What is claimed is:

1. A semiconductor device, comprising:
a substrate;
a gate dielectric overlying the substrate;
a gate electrode overlying the gate dielectric;
source/drain regions adjacent to opposite sides of the gate electrode;
a layer of refractory metal or refractory metal compound overlying the gate electrode and source/drain regions; and
a metal alloy silicide overlying the layer of refractory metal or refractory metal compound.

2. The semiconductor device according to claim 1, wherein a contact etch stop layer (CESL) is formed on top of the formed metal alloy silicide.

3. The semiconductor device according to claim 1, wherein the substrate comprises Si and at least one of SiO₂, SiON, SiN, SiCO, SiCN, SiCON, and SiGe.

4. The semiconductor device according to claim 3, wherein the substrate is doped with at least one of H, B, P, As, and In.

5. The semiconductor device according to claim 1, wherein the device is a FinFET.

6. The semiconductor device according to claim 1, wherein the gate electrode comprises at least one of the following materials: Ti, Pt, Pd, Co, and a Ni alloy silicide.

7. The semiconductor device according to claim 1, wherein the layer of refractory metal or refractory metal compound is about 4 Å to about 20 Å thick.

8. The semiconductor device according to claim 1, wherein the gate electrode comprises NiPtSi, NiPdSi, CoPtSi₂, or CoPdSi₂.

9. The semiconductor device according to claim 1, wherein the metal alloy silicide is about 50 Å to about 100 Å thick.

10. A semiconductor transistor comprising:
a gate dielectric overlying a substrate;
a gate electrode overlying the gate dielectric;
a spacer formed on sidewalls of the gate electrode;
a layer of refractory metal or refractory metal compound overlying active regions of the substrate; and
an MX metal alloy layer formed on the layer of refractory metal or refractory metal compound,
wherein the M is selected from the group consisting of Ti, Pt, Pd, Co, and Ni, and
further wherein the X includes an alloying additive.

11. The semiconductor transistor according to claim 10, further comprising a capping layer comprising TiN layer on the metal alloy layer.

12. The semiconductor transistor according to claim 10, wherein the alloying additive is selected from the group consisting of: C, Al, Si, Sc, Ti, V, Cr, M, Fe, Co, Ni, Cu, Ge, Y, Zr, Nb, Mo, Ru, Rh, Pd, In, Sn, La, Hf, Ta, W, Re, Ir, Pt, Ce, Pr, Nd, Sm, Eu, Gd, Tb, Dy, Ho, Er, Tm, Yb, Lu, and mixtures thereof.

13. The semiconductor device according to claim 10, wherein a contact etch stop layer (CESL) is formed on top of the formed metal alloy layer.

14. The semiconductor device according to claim 10, wherein the substrate and spacer comprise Si and at least one of SiO₂, SiON, SiN, SiCO, SiCN, SiCON, and SiGe.

15. The semiconductor device according to claim 14, wherein the substrate and spacer are doped with at least one of H, B, P, As, and In.

16. The semiconductor device according to claim 10, wherein the transistor is a FinFET.

17. The semiconductor device according to claim 10, wherein the gate electrode comprises at least one of the following materials: Ti, Pt, Pd, Co, and a Ni alloy silicide.

18. The semiconductor device according to claim 10, wherein the layer of refractory metal or refractory metal compound is about 4 Å to about 20 Å thick.

19. The semiconductor device according to claim 10, wherein the gate electrode comprises NiPtSi, NiPdSi, CoPtSi₂, or CoPdSi₂.

20. The semiconductor device according to claim 10, wherein the MX metal alloy layer is about 50 Å to about 200 Å thick.
